(19) United States
(12) Patent Application Publication
(10) Pub. No.: US 2025/0112075 A1
(43) Pub. Date: Apr. 3, 2025

(54) METAL BONDED ESC WITH OUTER CERAMIC VACUUM ISOLATION RING FOR CRYOGENIC SERVICE

(71) Applicant: Applied Materials, Inc., Santa Clara, CA (US)

(72) Inventors: Alexander SULYMAN, Santa Clara, CA (US); Timothy Joseph FRANKLIN, Campbell, CA (US); Jaeyong CHO, San Jose, CA (US); Joseph F. SOMMERS, San Jose, CA (US); Joseph F. BEHNKE, Santa Clara, CA (US); Sajad YAZDANI, Santa Clara, CA (US); Xue CHANG, San Jose, CA (US); Kartik RAMASWAMY, San Jose, CA (US); Tomoaki KOHZU, Santa Clara, CA (US); Kyounghwan NA, Santa Clara, CA (US)

(21) Appl. No.: 18/375,339

(22) Filed: Sep. 29, 2023

(51) Int. Cl. H01L 21/683; H01J 37/32; H01L 21/67; H01L 21/687

(52) U.S. Cl. CPC H01L 21/6833; H01J 37/32724; H01L 21/67103; H01L 21/68785; H01J 2237/002

(57) ABSTRACT

Embodiments of the present disclosure herein include an apparatus for processing a substrate. More specifically, embodiments of this disclosure provide a substrate support assembly that includes an electrostatic chuck (ESC) assembly. The ESC assembly comprises a cooling base having a top surface and an outer diameter sidewall, an ESC having a substrate support surface, a bottom surface and an outer diameter sidewall, the bottom surface of the ESC coupled to the top surface of the cooling base by a metal bond layer. The substrate support assembly includes a blocking ring disposed around the metal bond layer.

### BACKGROUND

### Field

Embodiments of the present disclosure generally relate to apparatus and methods for fabricating semiconductor devices. More specifically, apparatus disclosed herein relate to an electrostatic chuck assembly for use in a plasma processing chamber.

### Description of the Related Art

Semiconductor substrates are processed for a wide variety of applications, including the fabrication of integrated devices and micro devices. One such processing device is a plasma processing chamber. During processing, the substrate is positioned on an electrostatic chuck assembly within the plasma processing chamber. The electrostatic chuck assembly may have an electrostatic chuck, a cooling base, a facility plate and/or a base. The ESC is typically bonded in the electrostatic chuck assembly.

A plasma is formed in the plasma processing chamber for processing the substrate. During plasma processing, tight controls over substrate temperature along with the shape of the plasma over the substrate are used to obtain good and consistent results. Temperature uniformity is provided by a plurality of heaters in the ESC along with a cooling base. The shape of the plasma is influenced by electrodes in the ESC as well as the shape of the ESC facing the plasma, i.e., process rings. Process skew may occur due to the plasma coupling to the ESC and/or non-uniformity of the temperature across the ESC negatively impacting process performance.

The ESC may require extreme processing temperatures during certain operations. The ESC may therefore be configured specifically for high or low temperatures depending on the processing requirements, such as some etching operations require extremely low temperatures. At extremely low temperatures, the ESC may be operating at a temperature of 0 degrees Celsius or less. However, typical ESCs use elastomeric bonds which not only have low thermal conductivity, but also are limited a low operational temperatures due to relatively high glass transition temperatures which lead to sharp increases in Young's modulus at these low temperatures leading to the breakdown of the ESC bond material due to shear stress.

Therefore, there is a need for an improved electrostatic chuck assembly to improve process performance at low temperatures.

### SUMMARY

Embodiments of the present disclosure include an apparatus for processing a substrate. More specifically, embodiments of this disclosure provide a substrate support assembly that includes an electrostatic chuck (ESC) assembly. The ESC assembly includes a cooling base having a top surface and an outer diameter sidewall, and an ESC having a substrate support surface, a bottom surface and an outer diameter sidewall. The bottom surface of the ESC is coupled to the top surface of the cooling base by a metal bond layer. The substrate support assembly includes a blocking ring disposed around the metal bond layer.

Embodiments of the present disclosure further provides a processing chamber. The processing chamber includes a chamber body having a lid, bottom and sidewalls defining an interior volume. An electrostatic chuck (ESC) assembly is disposed in the interior volume. The ESC assembly includes a cooling base having a top surface and an outer diameter sidewall, and an ESC having a substrate support surface, a bottom surface and an outer diameter sidewall. The bottom surface of the ESC is coupled to the top surface of the cooling base by a metal bond layer. The substrate support assembly includes a blocking ring disposed around the metal bond layer.

Embodiments of the present disclosure may further provide a substrate support assembly that includes an electrostatic chuck (ESC). The substrate support assembly has a cooling base having a top surface and an outer diameter sidewall. The substrate support assembly further has an ESC having a substrate support surface, a bottom surface and an outer diameter sidewall. The ESC has a chucking electrode disposed therein. A facility plate is disposed below and in contact with the cooling base. A backside gas inlet extends through the substrate support and configured to supply a gas to the substrate support surface. A lift pin extends through the ESC and a lift pin guide extending into the ESC.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a cross-sectional schematic view of an exemplary plasma chamber including substrate support assembly according to an embodiment.

FIG. 2 is a cross-sectional schematic view illustrating a portion of the substrate support assembly having a lift pin, according to an embodiment.

FIG. 3 is a cross-sectional schematic view illustrating another portion of the substrate support assembly having a backside gas inlet, according to an embodiment.

FIG. 4 is a cross-sectional schematic view illustrating yet another portion of the substrate support assembly having a locking feature, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein provide a substrate support assembly that includes a blocking ring that protects a metal bond between an electrostatic chuck (ESC) and a cooling base. The metal bond improves thermal conductivity for cooling a substrate during cryogenic operations, while the blocking ring helps protect the metal bond from the processing environment and arcing from the metal bond.

The substrate support assembly described below may be utilized in an etch processing chamber and in other types of plasma and non-plasma enhanced processing chambers such as, physical vapor deposition chambers, chemical vapor deposition chambers, ion implantation chambers, among others, and other systems where protection of the bond layer disposed between an cooling base and an ESC is desirable.

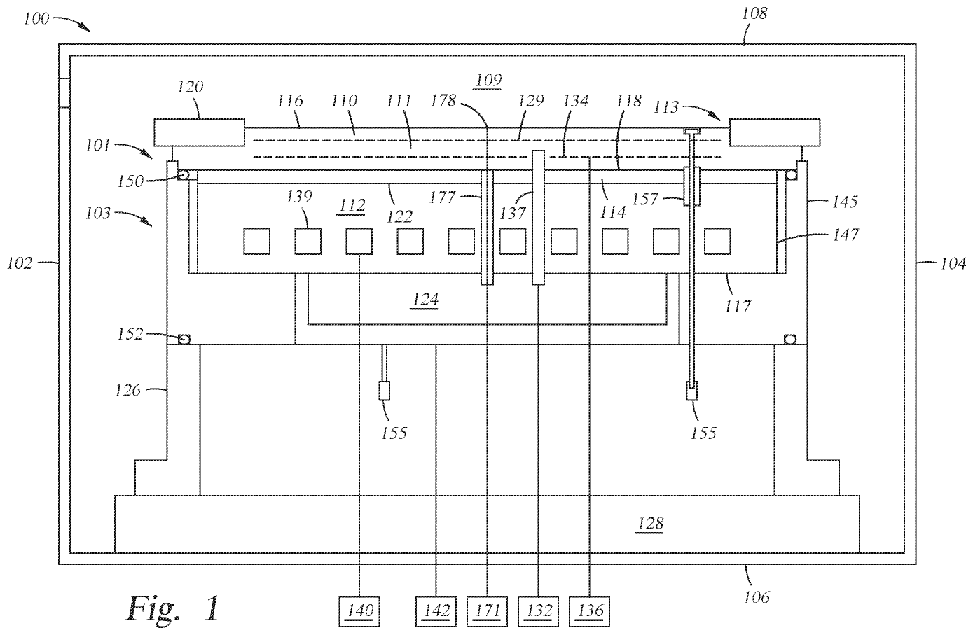

FIG. 1 is a cross-sectional schematic view of an exemplary plasma chamber 100A including substrate support assembly 101, according to an embodiment. The substrate support assembly 101 may be utilized in multiple types of plasma processing chambers, for example plasma treatment chambers, annealing chambers, physical vapor deposition chambers, chemical vapor deposition chambers, and ion implantation chambers, among others, as well as other systems where protection of adhesive layers within the substrate support assembly 101 from environmental conditions within the plasma processing chamber 100A is desirable. It is also contemplated that the disclosure may be used to advantage in processing chambers that utilize plasmas.

The plasma processing chamber 100A includes a chamber body 102 having sidewalls 104, a bottom 106 and a lid 108 that enclose a processing region 109. The substrate support assembly 101 is disposed in the processing region 109. The substrate support assembly 101 includes an electrostatic chuck assembly 103 (ESC assembly), a facility plate 124, an insulator plate 126, a ground plate 128, and a blocking ring 145.

The ESC assembly 103 includes an electrostatic chuck (ESC) 110 and a cooling base 112. In certain embodiments, the ESC assembly 103 may be surrounded by a quartz processing kit (not shown). The ESC 110 is coupled to the cooling base 112 using a metal bond layer 114. The ESC assembly 103 may have lift pins 155 disposed therethrough and configured to extend above the substrate support surface 116 of the ESC 110. The ESC assembly 103 may have three or more lift pins 155 spaced to support a substrate thereon.

The ESC 110 includes a substrate support surface 116, a bottom surface 118, and a drop-off formed on the substrate support surface 116, forming a ledge 113 that supports an edge ring 120. The edge ring 120 horizontally extends beyond an outer perimeter of the ESC 110. In one embodiment, the ESC 110 is fabricated from a dielectric body 111 having an embedded chucking electrode 129. The dielectric body 111 may be a ceramic material, such as alumina (Al₂O₃), aluminum nitride (AlN) or other suitable material. Alternately, the dielectric body 111 of the ESC 110 may be fabricated from a polymer, such as polyimide, polyetheretherketone, polyaryletherketone and the like.

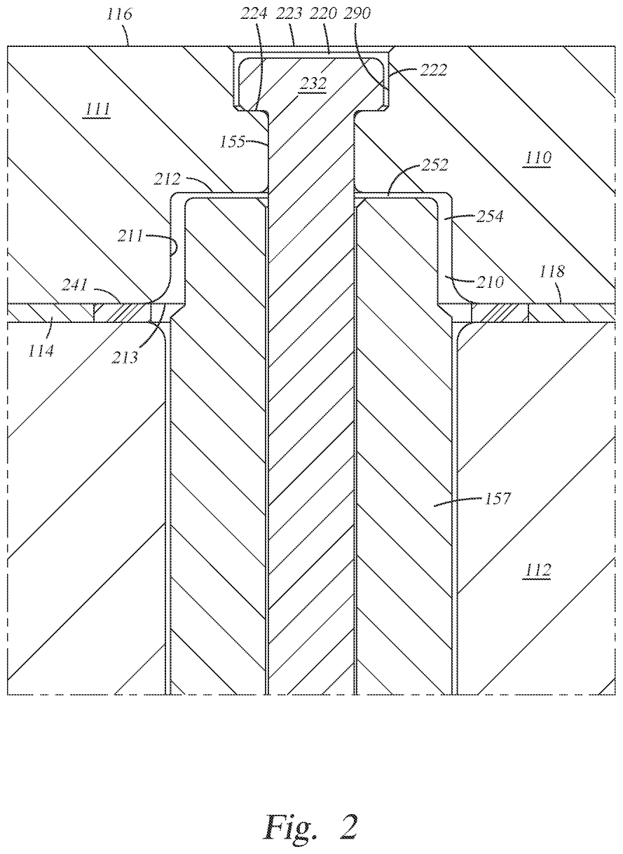

Turning briefly to FIG. 2, FIG. 2 is a cross-sectional schematic view illustrating a portion of the substrate support assembly 101 illustrating one of the lift pins 155, according to an embodiment. The lift pin 155 extends through a guide 157. The guide 157 extends through the cooling base 112, the metal bond layer 114 and into the ESC 110.

The dielectric body 111 of the ESC 110 has a recess 220 formed in the substrate support surface 116. The recess 220 extends through the substrate support surface 116 and into the dielectric body 111 of the ESC 110. The recess 220 has a recess bottom 224 and recess sidewalls 222 along with a pin head opening 223 formed along the substrate support surface 116 of the dielectric body 111. The size and shape of the recess 220 is configured to accept a lift pin head 232 of the lift pin 155.

During operation, the lift pin 155 is vertically movable through the guide 157 between a raised and a lowered position. When present in the processing chamber 100, the substrate is supported on the lift pin head 232 when the lift pin 155 is extended to elevate the lift pin head 232 above the substrate support surface 116, such that the substrate is spaced from the substrate support surface 116 to allow transfer to and from the substrate support assembly 101. When present in the processing chamber 100, the substrate is supported on the substrate support surface 116 when the lift pin 155 is retracted to a position where the lift pin head 232 is below the substrate support surface 116, such that the substrate rests on the substrate support surface 116.

The dielectric body 111 of the ESC 110 has a cavity 210 formed in the bottom surface 118. The cavity 210 extends through the bottom surface 118 and into the dielectric body 111 of the ESC 110. The cavity 210 has a cavity bottom 212 and cavity sidewalls 211 along with an opening 213 formed along the bottom surface 118 of the dielectric body 111.

The guide 157 extends through the opening 213 to the cavity bottom 212. The guide 157 may be formed from a thermoplastic with high melting point, such as above 280 degrees Celsius which has good chemical resistance. For example, the guide 157 may be formed from polyphenylene sulfide (PPS), polyetheretherketone (PEEK), ceramic, or other suitable material.

In some examples, a first gap 252 may be formed between the guide 157 and the cavity bottom 212. A second gap 254 may be formed between the guide 157 and the cavity sidewalls 211. The first gap 252 may be between 10 mil and 16 mil. An adhesive material, for example a silicone potting material, may be disposed between the guide 157 and the cavity bottom 212 in the first gap 252. The adhesive material may additionally be disposed between the guide 157 and the cavity sidewalls 211 in the second gap 254. The adhesive material reduces the stress due to thermal expansion between the guide 157 and the body 201 of the ESC 110.

Optionally, a seal 241 may be placed between ESC 110 and the cooling base 112 adjacent the metal bond layer 114 and the guide 157. The seal 241 protects the metal bond layer 114. In one example, the seal 241 is formed from a silicone sealant, a silicon gasket, a silicon o-ring, or other suitable seal. The seal 241 may alternatively be formed from other suitable materials.

A path 290 is formed from the substrate support surface 116 to the bottom surface 118 along recess sidewalls 222, the side wall lift pin 155, cavity bottom 212 and cavity sidewalls 211. The cavity 210 in the dielectric body 111 of the ESC 110 beneficially extends the length of the path 290 over conventional ESCs without the cavity. The cavity sidewalls 211 increases the length of an interface between the bond layer and the guide 157 by around 50% to about 150% compared to conventional ESCs, for example the path 290 is increased from about 0.10 inch to 0.20 inches. It should be appreciated that the path 290 is dependent on the particular dimensions of the cavity 210 which allows for a different diameter the guide 157 or the depth the cavity 210. The long and non-linear routing of the path 290 additionally increases the distance from the chamber environment to the metal bond layer 114, which enhances the protection of the metal bond layer 114 from gases present in the chamber environment.

Returning to FIG. 1, the ESC 110 optionally includes a plurality of backside gas holes 178 extending through the substrate support surface 116. The backside gas holes 178 are coupled to a backside gas source 171. During processing or cleaning, a gas may be supplied from the backside gas source 171 through the backside gas holes 178 to the underside of a substrate or cover plate. In one example, the backside gas source 171 provides an inert gas, for example, helium.

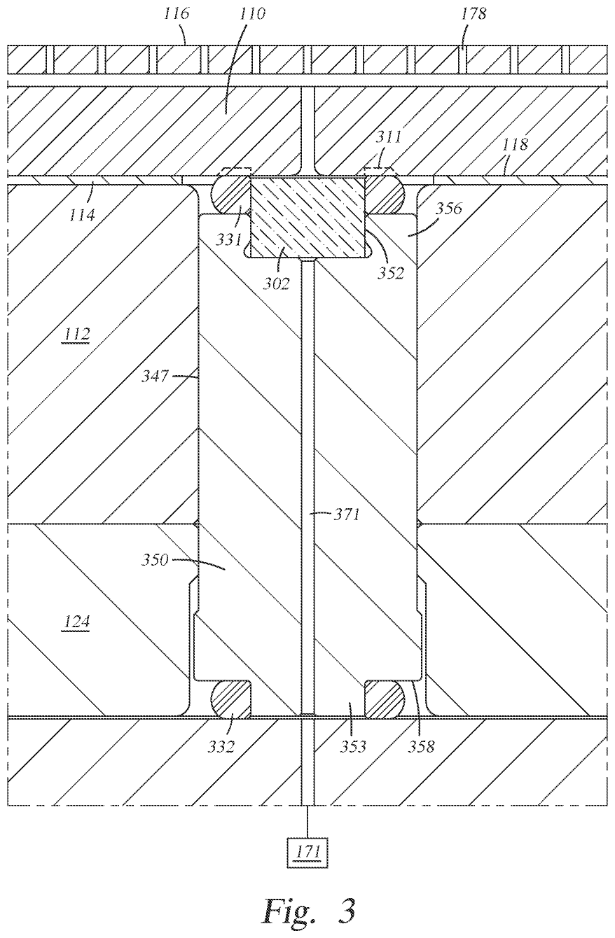

Turning now to a cross-sectional schematic view of FIG. 3 illustrating another portion of the substrate support assembly having a backside gas inlet 371. The backside gas holes 178 are fluidly coupled to the backside gas source 171 through the backside gas inlet 371. A cartridge 350 is disposed about the backside gas inlet 371. The cartridge 350 has an outer sidewall 347, a top surface 356 and a bottom surface 358. A recess 352 extends into the cartridge 350 along the top surface 356. A protrusion 353 extends outward and away from the cartridge 350 at the bottom surface 358. The top surface 356 of the cartridge 350 is disposed adjacent the bottom surface 118 of the ESC 110. The cartridge 350 extends through the cooling base 112 and may extend further into or through the facility plate 124. The cartridge 350 may be formed of ceramic or other suitable material for operating at temperatures between about −60 degrees Celsius and about 90 degrees Celsius. For example, the cartridge 350 may be formed from an aluminum oxide. The cartridge 350 is configured to be removeable, i.e., replaceable. In one example, the cartridge 350 extends into the insulator plate 126. The cartridge 350 is sealed at the ESC 110 and the facility plate 124 to allow backside gas to pass through the cartridge 350.

A porous insert 302 may optionally fluidly couple the cartridge 350 to the backside gas holes 178 in the ESC 110. The porous insert 302 is configured to prevent backside gas leak along the interface between the cartridge 350 and the backside gas holes 178. The porous insert 302 also helps to arrest arcing paths through the helium passages. The porous insert 302 may extend into the recess 352 in the top surface 356 of the cartridge 350.

The cartridge 350 provides a seal for the ESC 110 to be maintained in a vacuum environment while the facility plate 124 is maintained at atmospheric pressure. To provide the vacuum seal, a first o-ring 331 is disposed between the cartridge 350 and the ESC 110. Additionally, a second o-ring 332 may be disposed between the cartridge 350 and the cooling base 112. In other embodiments, the second o-ring 332 may be disposed between the cartridge 350 and the facility plate 124.

The first o-ring 331 may circumscribe the porous insert 302. Alternately, the first o-ring 331 may have an inward sealing surface which overlaps the interface between the porous insert 302 and the ESC 110. The ESC 110 may optionally have a first seal groove 311 disposed therein the bottom surface 118 of the ESC 110 for accepting or aligning the first o-ring 331. The first o-ring 331 may be formed from a hybrid material, silicone material or other suitable material for cryogenic operations. The first o-ring 331 additionally protect the metal bond layer 114 from the processing environment.

The second o-ring 332 may circumscribe the lower protrusion 353 of the cartridge 350. The second o-ring 332 may be formed from a hybrid material, silicone material or other suitable material for cryogenic operations. The second o-ring 332 provides a vacuum seal between the cartridge 350 and the substrate support assembly 101.

Returning to FIG. 1, the chucking electrode 129 of the ESC 110 may be configured as a mono polar or bipolar electrode, or have another suitable arrangement. The chucking electrode 129 is coupled through an RF filter (not shown) to a chucking power source 132, which provides a DC power to electrostatically secure a substrate to the substrate support surface 116 of the ESC 110.

The ESC 110 optionally includes one or more resistive heaters 134 embedded therein. The resistive heaters 134 are utilized to elevate the temperature of the ESC 110 to the processing temperature suitable for processing a substrate disposed on the substrate support surface 116. The resistive heaters 134 are coupled through the facility plate 124 to an optional heater power source 136. The heater power source 136 may provide 500 watts or more power to the resistive heaters 134. The heater power source 136 includes a controller (not shown) utilized to control the operation of the heater power source 136, which is generally set to heat the substrate to a predetermined temperature. In one embodiment, the resistive heaters 134 include a plurality of laterally separated heating zones, wherein the controller enables at least one zone of the resistive heaters 134 to be preferentially heated relative to the resistive heaters 134 located in one or more of the other zones. For example, the resistive heaters 134 may be arranged concentrically in a plurality of separated heating zones. The resistive heaters 134 maintain a substrate at a processing temperature suitable for processing. In one embodiment, the processing temperature is not greater than about −50 degrees Celsius. For example, the processing temperature is between about −50 degrees Celsius to about −150 degrees Celsius. In yet other examples, the processing temperature is greater than about −50 degrees Celsius. For example, the processing temperature is between −50 degrees Celsius to about +150 degrees Celsius.

The cooling base 112 includes at least one cooling zone 139 that are each coupled to a coolant supply 140. When multiple cooling zones 139 are present, the cooling zones 139 may be arranged concentrically or in other suitable manner. For example, an inner cooling zone may be provided under the substrate support surface 116 while an outer cooling zone may be provided along the outer perimeter and optionally extending under the edge ring 120.

A top surface 122 of the cooling base 112 is coupled to the bottom surface 118 of the ESC 110 using the metal bond layer 114. Metallic bonds can offer a lower wafer temperature than other elastomeric bond materials for a given coolant temperature due to high thermal conductivity. In one example, the metal bond layer 114 is formed from material containing indium. The metal bond layer 114 may have a room temperature Young's Modulus in a range of about 1.90×10⁶ PSI to about 1.40×10⁶ PSI, such as about 1.57×10⁶ PSI. The metal bond layer 114 may have a thermal conductivity in a range of about 75 W/m-k to about 90 W/m-k, such as about 86 W/m-k. The ductility and thermal conductivity making the metal bond ideal as a compressible thermal interface material. The metal in the adhesive results in only about a 1 degree Celsius drop across the metal bond layer 114 as opposed to conventional adhesives without metal which have about a 35 degree Celsius drop across the metal bond layer 114. Thus, the metal indium may reduce the thermal resistance, or improve the thermal conductivity, of the metal bond layer 114 by 90 degrees Celsius or more to reduce the temperature at the substrate. The improved thermal conductivity results in substrate temperatures that can be reduced by about 30 percent to about 50 percent over conventional designs. The cooler substrate temperatures enable the use of higher temperature fluids in the cooling base 112 for cooling the ESC 110, and thus the substrate. The improved cooling of the substrate in cryogenic applications reduces the cost for additional cooling by the cooling base 112.

As the metal material of the metal bond layer 114 is also electrically conductive, a problem may arise in high power ESC designs as the metal bond layer 114 can become an arc point. Isolation of the metal bond layer 114 from the process vacuum is desirable to prevent arcing, but also prevents metal contamination and bond erosion. The blocking ring 145 protects the metal bond layer 114 and first seal 150. The result is a metal bonded electrostatic chuck (ESC) utilizing a ceramic ring at the ESC periphery which isolates the metallic bond material and cooling plate from the process vacuum. The outer diameter of the cooling base 112 and the outer diameter of the ESC 110 are on opposite sides of the vacuum seal while the blocking ring 145 functions as a plasma blocker to prevent erosion of the metal bond layer 114 between the ESC 110 and cooling base 112, and allows for the RF hot cooling base 112 to remain almost entirely at atmospheric pressure, which advantageously mitigates potential arcing.

In one embodiment, blocking ring 145 may be disposed between the ESC 110 and top surface 117 of the insulator plate 126 that extend past the cooling base 112 on both sides of the substrate support assembly 101. Stated otherwise, the blocking ring 145 is disposed around an outer diameter sidewall 147 of the cooling base 112. In one example, blocking ring 145 is made from ceramic or other dielectric material. In one embodiment, a first seal 150 forms a vacuum seal between the blocking ring 145 and the ESC 110. A second seal 152 forms a vacuum seal between the blocking ring 145 and the insulator plate 126. The first seal 150 may be an O-ring. The first seal 150 may be formed from a material suitable for maintaining a vacuum at temperatures less than about −60° Celsius, such as about −150° Celsius. The first seal 150 may be formed from a hybrid material such as silicone/polytetrafluoroethylene (PTFE). The second seal 152 may also be formed from a hybrid material such as silicone/polytetrafluoroethylene (PTFE).

The outer perimeter of the cooling base 112 is fully isolated from chamber process gas by a vacuum seal. Alternatively, the blocking ring 145 may be sealed to the ESC 110 and the facility plate 124 using bonding material in lieu of seals. The bonding material may be a silicone based adhesive, an epoxy, or other suitable adhesive. Thus, the blocking ring 145 allows higher pressure, for example ambient pressure, to be utilized within portions of the substrate support assembly 101 disposed inward of the blocking ring 145, which also mitigates potential arcing within the substrate support assembly 101.

The facility plate 124 is disposed under the cooling base 112. The facility plate 124 is supported by a ground plate 128 and is configured to facilitate electrical, cooling, heating, and gas connections with the substrate support assembly 101. The ground plate 128 is supported by the bottom 106 of the processing chamber. An insulator plate 126 insulates the facility plate 124 from the ground plate 128. Stated differently, the insulator plate 126 is disposed above ground plate 128 and surrounds the facility plate 124. There may be an optional gap 125 defined between the facility plate 124 and the insulator plate 126. The distance of gap 125 may be between 0.002 inches and 0.010 inches. The gap 125 helps slow the transfer of heat between the facility plate 124 and the insulator plate 126. A top surface 117 of the insulator plate 126 horizontally extends beyond the cooling base 112. Stated differently, the insulator plate 126 is wider than the cooling base 112.

The facility plate 124 may include an optional cooling channel (not shown) that may be coupled to an optional coolant supply 142. When present, the coolant supply 142 provides a coolant that, in one example, can maintain the facility plate 124 at an ambient temperature of between about 25 degrees Celsius to about 35 degrees Celsius. The coolant provided by the coolant supply 142 is a heat transfer fluid, and in some examples, is a refrigerant. The coolant supply 142 provides the coolant that is circulated through a coolant channel (not shown) of the facility plate 124. The coolant flowing through the coolant channel enables the facility plate 124 to be maintained at the predetermined ambient temperature, which assists in maintaining the insulator plate 126 at the predetermined ambient temperature.

The insulator plate 126 is disposed below the facility plate 124. Alternately, the insulator plate 126 may surround the facility plate 124. The blocking ring 145 shields the gaps between the facility plate 124 and the cooling base 112, ensuring the facility plate 124 has no direct line of sight to the sidewalls of the plasma chamber 100 so that potential for arcing there between is reduced.

Components of the substrate support assembly 101 may be coupled to each other using fasteners. For example, the ground plate 128 may be coupled to the insulator plate 126 using a fastener, the insulator plate may be coupled to the facility plate 124 using a fastener, and the insulator plate may be coupled to the cooling base 112 using a fastener. In one example, a locking feature 137 is provided between the ESC 110 and the cooling base 112. The locking feature 137 may couple the ESC 110 and the cooling base 112 together.

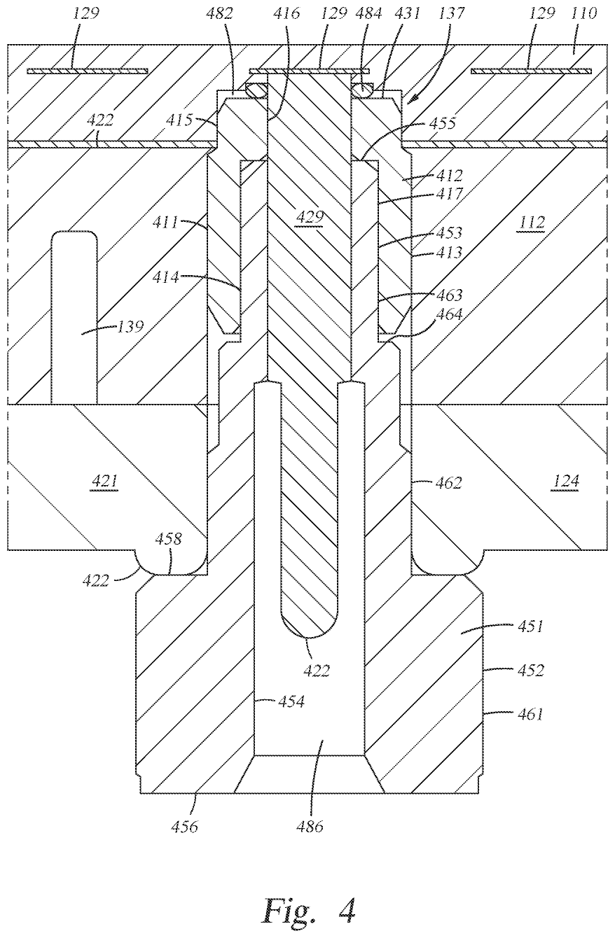

FIG. 4 is a cross-sectional schematic view illustrating yet another portion of the substrate support assembly showing the locking feature 137, according to an embodiment. The locking feature 137 has a bushing 412 and an insulator 452. The locking feature 137 may include additional components to prevent movement between the ESC 110 to the cooling base 112 while accommodating differences in thermal expansion between the ESC 110 to the cooling base 112.

The ESC 110 has an electrode terminal 429. The electrode terminal 429, the bushing 412 and the insulator 452 fit together to lock the ESC 110 to the cooling base 112. For example, the insulator 451 is disposed inward of the bushing 412 and around the electrode terminal 429. The electrode terminal 429 is electrically coupled to the embedded chucking electrode 129. The electrode terminal 429 is configured to provide power from the chucking power source 132. The electrode terminal 429 has a top portion 421 and a bottom portion 422. In one example, the top portion 421 of the electrode terminal 429 is brazed to an electrical connection in the ESC 110. Thus, the electrode terminal 429 is fixed to the ESC 110. In one example, the top portion 421 has a larger horizontal cross-section than a horizontal cross-section of the bottom portion 422. In examples wherein the horizontal cross-section of the bottom portion 422 and top portion 421 are circular, the diameter of the top portion 421 is larger than the diameter of the bottom portion 422.

The bushing 412 is fitted into a top surface 442 of the cooling base 112. The bushing 412 may be formed from a non-conductive creep resistant material such as polyimide, ceramic or other suitable material. The bushing 412 may have a body 411 that is ring shaped. The ring shape of the body 411 has a top outer diameter 415, a bottom outer diameter 413, a top inner diameter 416 and a bottom inner diameter 417. A radius of the top inner diameter 416 is smaller than a radius of the bottom inner diameter 417. Likewise, a radius of the top outer diameter 415 is smaller than a radius of the bottom outer diameter 413. In one example, the bushing 412 is press fit into a hole in the cooling base 112. The bottom outer diameter 413 is sized to the hole in the cooling base 112. The top inner diameter 416 is sized to accept the top portion 421 of the electrode terminal 429. That is, the bushing 412 is fixed to the cooling base 112.

The insulator 452 has a body 451. The body 451 is ringed shaped and has a top 455 and a bottom 456. The body has a first outer diameter 461 disposed proximate the bottom 456, a third outer diameter 463 disposed proximate the top 455 and a second outer diameter 462 disposed between the first outer diameter 461 and the third outer diameter 463. A radius of the first outer diameter 461 is greater than a radius of the second outer diameter 462. The radius of the second outer diameter 462 is greater than a radius of the third outer diameter 463. A first shoulder 458 is perpendicular to and disposed between the first outer diameter 461 and the second outer diameter 462. A second shoulder 464 is perpendicular to and disposed between the second outer diameter 462 and the third outer diameter 463. The body 451 has first inner diameter 454 disposed proximate the bottom 456 and a second inner diameter 453 disposed proximate the top 455. The first inner diameter 454 has a larger radius than the second inner diameter 453.

The second inner diameter 453 is sized to accept the top portion 421 of the electrode terminal 429 and the third outer diameter 463 is sized to fit in the bottom inner diameter 417 of the bushing 412 and creates an overlap 414. The top 455 of the insulator 452 contacts an inner shoulder of the bushing 412 disposed between the top inner diameter 416 and the bottom inner diameter 417. The electrode terminal 429 extends toward the bottom 456 of the insulator 452 beyond the overlap 414 and short of the bottom 456. The overlap 414 of the bushing 412 and the insulator 452 prevents the electrode terminal 429 from electrically coupling to the cooling base 112 and arcing. The second shoulder 464 is configured to extend below and outward from the overlap 414. The first shoulder 458 is disposed below and in contact with the facility plate 124. The first shoulder 458 pulls the facility plate 124 in place and up against the cooling base 112. Thus, the electrode terminal 429, bushing 412 and insulator 452 of the locking feature 137 hold, or lock, the facility plate 124, the cooling base 112 and ESC 110 together.

A bottom cavity 486 is disposed at the first inner diameter 454 of the insulator 452. The bottom portion 422 of the electrode terminal 429 extends into the cavity 486 for electrically coupling to the chucking power source 132.

The locking feature 137 optionally include a seal 484 disposed between a top surface 431 of the bushing 412 and the ESC 110. The seal 484 may be disposed in a gap 482 formed between the bushing 412 and the ESC 110. Alternately, or in conjunction with the seal 484, the gap 482 may be filled with silicone, or other suitable material, for maintaining a seal and preventing arcing. For example, the gap 482 may be potted with silicone rated for temperatures as low as −60 C.

Advantageously, the metal bond improves thermal conductivity for cooling the substrate during cryogenic operations while the blocking ring helps protect the metal bond from the processing environment and arcing from the metal bond. Thus, the metal bond increases ESC cryogenic performance while the blocking ring helps to prevent arcing and bond degradation to prolong time between maintenance while preserving the processing environment from chamber contaminants from the metal bond.

In addition to the examples described above, some additional non-limiting examples may be described as follows.

Example 1A. A substrate support assembly comprising:
an electrostatic chuck (ESC) assembly comprising:
   a facility plate;
   a cooling base disposed on the facility plate and having a top surface and an outer diameter sidewall;
   an ESC having a substrate support surface, a bottom surface, a plurality of backside gas holes extending through the substrate support surface fluidly coupled to a backside gas source through a backside gas inlet; and
   a cartridge disposed about the backside gas inlet 371 wherein the cartridge extends through the cooling base and into the facility plate.

Example 1B. The substrate support assembly of example 1A, wherein the cartridge is formed of aluminum oxide and suitable for operating at temperatures between about-60 degrees Celsius and about 90 degrees Celsius, the cartridge is fluidly sealed to the ESC and to the facility plate.

Example 2A. A substrate support assembly comprising:
an electrostatic chuck (ESC) assembly comprising:
   a cooling base having a top surface and an outer diameter sidewall;
   an ESC having a substrate support surface, a bottom surface, an electrode embedded therein, and an electrode terminal coupled to the electrode and extending through the bottom surface; and
   a locking feature 137 coupling the ESC 110 to the cooling base 112, the locking feature comprising:
      a bushing; and
      an insulator disposed inward of the bushing and around the electrode terminal.

Example 2B. The substrate support assembly of example 2A, wherein the insulator has an outer diameter sized to fit in an inner diameter of the bushing creating an overlap between the insulator, and wherein the electrode terminal extends toward a bottom of the insulator beyond the overlap and short of the bottom of the insulator.

While the foregoing is directed to specific embodiments, other and further embodiments may be devised without departing from the basic scope thereof, and the scope thereof is determined by the claims that follow.

What is claimed is:

1. A substrate support assembly comprising:
an electrostatic chuck (ESC) assembly comprising:
a cooling base having a top surface and an outer diameter sidewall; and
an ESC having a substrate support surface, a bottom surface and an outer diameter sidewall;
a metal bond layer adhering the bottom surface of the ESC to the top surface of the cooling base; and
a blocking ring disposed around the metal bond layer.

2. The substrate support assembly of claim 1, wherein the ESC and cooling base are configured for cryogenic operations below 0 degrees Celsius.

3. The substrate support assembly of claim 2, wherein the metal bond layer is formed from a material containing indium.

4. The substrate support assembly of claim 3, wherein the blocking ring is disposed around the outer diameter sidewall of the cooling base.

5. The substrate support assembly of claim 4, wherein the blocking ring is disposed around the outer diameter sidewall of the ESC.

6. The substrate support assembly of claim 3, wherein the metal bond layer is formed from indium.

7. The substrate support assembly of claim 3, wherein the metal bond layer has a room temperature Young's Modulus between about 1.40×10⁶ PSI and about 1.90×10⁶ PSI with a thermal conductivity in a range of about 75 W/m-k to about 90 W/m-k.

8. A semiconductor processing chamber comprising:
a chamber body having a lid, bottom and sidewalls defining an interior volume;
an electrostatic chuck (ESC) assembly disposed in the interior volume, the ESC assembly comprising:
an ESC having a substrate support surface and a bottom surface;
a cooling base disposed under the bottom surface of the ESC, wherein a portion of the bottom surface of the ESC horizontally extends beyond a top surface of the cooling base;
a metal bond layer bonding the ESC to the cooling base;
a blocking ring disposed around the metal bond layer; and
a facility plate disposed under the cooling base, wherein the bottom surface of the cooling base horizontally extends beyond the facility plate.

9. The semiconductor processing chamber of claim 8, wherein the ESC and cooling base are configured for cryogenic operations below 0 degrees Celsius.

10. The semiconductor processing chamber of claim 9, wherein the metal bond is formed from indium.

11. The semiconductor processing chamber of claim 10, wherein the blocking ring is disposed around an outer diameter of the cooling base.

12. The semiconductor processing chamber of claim 11, wherein the blocking ring is disposed around the outer diameter of the ESC.

13. The semiconductor processing chamber of claim 10, wherein the metal bond is formed from indium.

14. The semiconductor processing chamber of claim 10, wherein the metal bond layer has a room temperature Young's Modulus between about 1.40×10⁶ PSI and about 1.90×10⁶ PSI with a thermal conductivity in a range of about 75 W/m-k to about 90 W/m-k.

15. A substrate support assembly comprising:
a cooling base having a top surface and an outer diameter sidewall;
an electrostatic chuck (ESC) having a substrate support surface, a bottom surface and an outer diameter sidewall, the ESC having a chucking electrode disposed therein;
a facility plate disposed below and in contact with the cooling base;
a backside gas inlet extending through the substrate support and configured to supply a gas to the substrate support surface;
a lift pin extending through the ESC; and
a lift pin guide, the lift pin guide extending into the ESC.

16. The substrate support assembly of claim 15 further comprising:
a locking assembly coupling to the chucking electrode in the ESC, the locking assembly configured to secure the facility plate in place and up against the cooling base.

17. The substrate support assembly of claim 15 further comprising:
a removeable ring disposed about the backside gas inlet in the substrate support assembly, wherein the ring has a recess along a top surface of the ring and a protrusion extending outward and away from the ring at a bottom surface of the ring.

18. The substrate support assembly of claim 17, wherein a top surface of the ring is disposed adjacent the bottom surface of the ESC and the ring extends through the cooling base to the facility plate.

19. The substrate support assembly of claim 18 further comprising:
a first o-ring disposed about the recess between the removeable ring and the ESC; and
a second o-ring disposed about the protrusion between the removeable ring and the facility plate.

20. The substrate support assembly of claim 15 wherein the lift pin guide is potted to the ESC.
